(19) United States
(12) Patent Application Publication
(10) Pub. No.: US 2010/0091447 A1
(43) Pub. Date: Apr. 15, 2010

(54) System and Method for Providing Liquid Cooling of Memory Devices

(75) Inventors: Christopher Jaggers, Austin, TX (US); Michael L. Krenek, Belton, TX (US); Travis North, Pflugerville, TX (US); James Bryan, Austin, TX (US)

Correspondence Address: LARSON NEWMAN & ABEL, LLP, 5914 WEST COURTYARD DRIVE, SUITE 200, AUSTIN, TX, 78730, US

(73) Assignee: Dell Products, LP, Round Rock, TX (US)

(21) Appl. No.: 12/249,075

(22) Filed: Oct. 10, 2008

(51) Int. Cl. H05K 7/20

(52) U.S. Cl. 361/679.47

(57) ABSTRACT

A device comprising a first thermal interface material, and a first micro-channel cold plate. The first thermal interface material is in physical communication with a first plurality of memory modules of a computer system. The first micro-channel cold plate is in physical communication with the first thermal interface material. The first micro-channel cold plate is adapted to allow a fluid flow through a first plurality of micro-channels, and configured to remove a first amount of heat produced by the first memory modules of the computer system through the first thermal interface material.

### FIELD OF THE DISCLOSURE

This disclosure generally relates to memory devices, and more particularly relates to a system and method for providing liquid cooling of memory devices.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

Memory modules and hard disk drives for workstations and desktops are sometimes placed in thermally restricting locations, such that it is difficult to obtain proper air flow to cool the memory modules and the hard disk drives. Thus, to provide proper amounts of thermal cooling to the memory module and hard disk drive, fans on the workstations and the desktops need to run at higher speeds or more fans need to be added to the workstations and the desktops. With an increase in either the fan speed or the number of fans, the acoustic level of the workstation and the desktop is also increased.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a schematic diagram of a micro-channel heat exchanger system for a computer system;

FIG. 2 is a schematic diagram of a portion of the micro-channel heat exchanger system taken along a line A-A in FIG. 1;

FIG. 3 is a schematic diagram of an alternative embodiment of the portion of the micro-channel heat exchanger system; and

FIG. 4 is a flow diagram of a method for transferring heat from a memory module to fluid inside a micro-channel cold plate of the micro-channel heat exchanger system.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application.

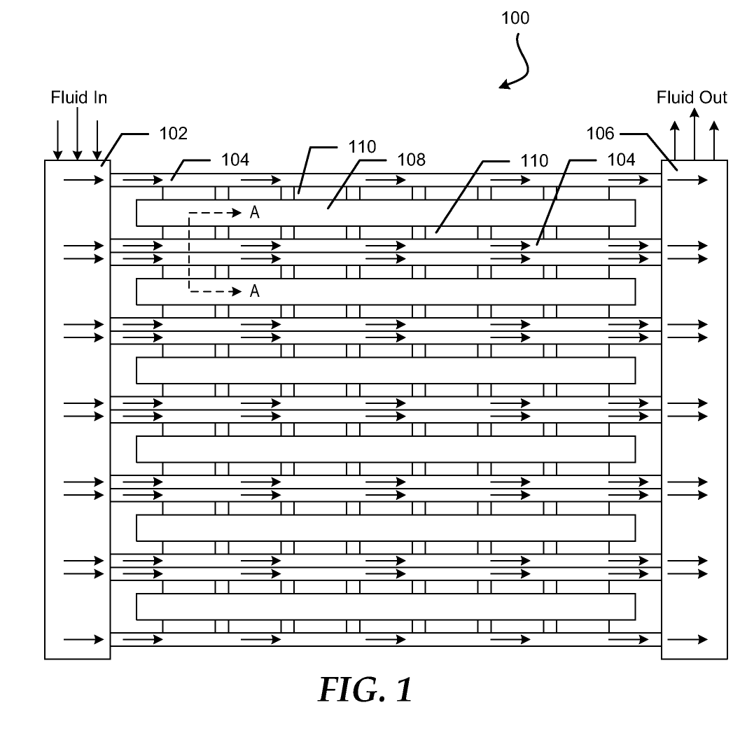

FIG. 1 shows a micro-channel heat exchanger system 100 for an information handling system. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communications between the various hardware components.

The micro-channel heat exchanger system 100 comprises an input channel 102, a plurality of micro-channel cold plates 104, and an output channel 106. The micro-channel cold plates 104 can be arranged in six parallel sections of two micro-channel cold plates each. Each section of micro-channel cold plates 104 is placed in physical communication with a dual sided circuit board 108 having a plurality of memory modules 110. The micro-channel cold plates 104 can extend the entire length of the memory modules 110. In different embodiments, the memory modules 110 can also be hard disk drives and the like.

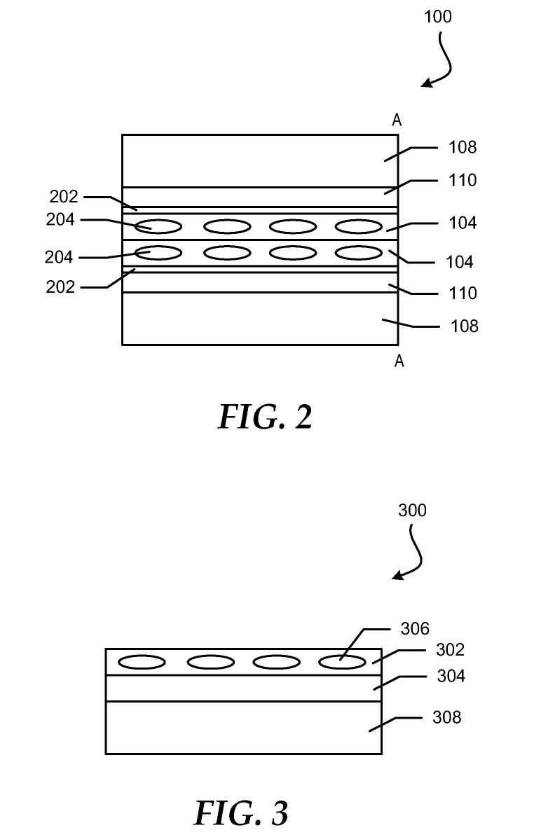

In an embodiment, the micro-channel cold plates 104 are preferably predominantly aluminum, such that the micro-channel cold plates can be thermally efficient in removing heat from each of the memory modules 110. The micro-channel cold plates 104 can remove the heat produced by the memory modules 110 through physical communication with the memory modules, and/or via a thermal interface material (TIM) placed between the micro-channel cold plate and the memory module as described below with respect to FIG. 2. Fluid can flow into the input channel 102, through the micro-channel cold plates 104, and out of the micro-channel heat exchanger system 100 through the output channel 106 to remove the heat transferred from the memory module 110 to the micro-channel cold plates. The fluid can preferably flow evenly through each of the micro-channel cold plates 104, such that every section of the micro-channel cold plates can remove a substantially equal amount of heat from each of the memory modules 110. In an embodiment, the micro-channel cold plates 104 can be any extruded aluminum part consisting of a plurality of channels having a hydraulic diameter preferably less than two millimeters.

FIG. 2 shows a portion of the micro-channel heat exchanger system 100 taken along the line A-A in FIG. 1. The micro-channel heat exchanger system 100 includes TIMs 202 and a plurality of micro-channels 204. The circuit boards 108 are in physical communication with the memory modules 110. The memory modules 110 are in physical communication with the TIMs 202, and the TIMs are in physical communication with the micro-channel cold plates 104. The micro-channels 204 are preferably located within the micro-channel cold plates 104.

As the memory modules 110 operate, heat is produced which needs to be removed so that damage is not caused to the memory modules. The TIMs 202 are preferably thermally conductive such that the heat produced by the memory modules 110 can be transferred to the micro-channel cold plates 104 via the TIMs. In different embodiments, based on the topology of the circuit board 108 and the memory module 110, the composition of the TIMs 202 can be a thin gap pad of filler material, a layer of grease, a phase change material, and/or any other material capable of transferring heat from the memory module to the micro-channel cold plate 104. The input channel 102 preferably provides the fluid flow through each of the micro-channels 204, such that the same amount of fluid is provided to each of the micro-channels.

Thus, the micro-channel heat exchanger system 100 can provide even heat transfer from each of the memory modules 110 to the micro-channel cold plates 104, and out of the liquid cooling heat exchanger system via the fluid flow through the input channel 102, the micro-channel cold plates, and the output channel 104. The fluid also preferably increases the thermal performance of the micro-channel cold plates 104 by continually removing the heat produced by the memory module 110 and transferred to the micro-channel cold plates. The fluid can also reduce an amount of noise produced by the computer system to cool the memory modules 110, hard disk drives, and the like as compared to only using cooling fans to remove this heat. For example, the fluid and the micro-channel cold plates 104 can allow the cooling fans to be run at lower speeds, such that the noise produced by the cooling fans is reduced.

FIG. 3 shows an alternative embodiment of the micro-channel heat exchanger system 300, which is preferably for use with a single hard disk drive. The micro-channel heat exchanger 300 includes a micro-channel cold plate 302, a TIM 304, and a plurality of micro-channels 306. The micro-channel cold plate 302 is in physical communication with the TIM 304, which is in physical communication with a spindle and printed circuit board components 308. The TIM 304 can be used to reduce contact resistance between the micro-channel cold plate 302 and the spindle and printed circuit board components 308, and to account for drive-to-drive component variations. The micro-channel cold plate 302 can exceed the required thermal performance for a computer system including the spindle and printed circuit board components 308 while preferably maintaining a relatively low fluid rate, with a low thermal resistance from the micro-channel cold plate 302 to the fluid, and with a low associated pressure drop.

The micro-channel heat exchanger system 300 can provide ample thermal margin to reduce idle level acoustics without compromising thermal performance. For example, the ample thermal margin can differ based on the embodiment of the micro-channel heat exchanger system 300, such that the fluid can be cooled a proper amount so when the fluid re-enters the micro-channel cold plate 302 the necessary amount of heat can be transfer from the micro-channel cold plate to the fluid. Additionally, the micro-channel heat exchanger system 300 can reduce the noise produced while cooling the computer system by reducing fan noise, while maintaining the required thermal performance or amount of heat transfer from the memory modules 110, hard disk drive, and the like.

Additionally, the reliability of the hard disk drive can be increased through consistent drive temperatures created by the fluid flow through the micro-channels 306. The fluid is preferably water based, such that it has a relative high heat capacity, which allows for very stable temperatures over periods of transient loading. Thus, based on the fluid flow through the micro-channels 204 and 308, the micro-channel heat exchanger 100 and the single hard disk drive micro-channel heat exchanger system 300 can provide stable operating temperatures for the memory modules 110, the spindle and printed circuit board components 306, and the like.

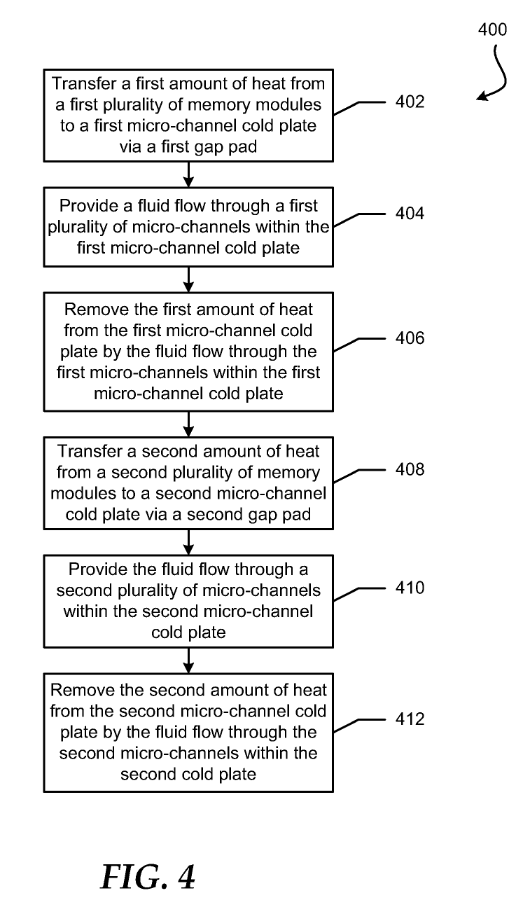

FIG. 4 shows a flow diagram of a method 400 for transferring heat from a memory module to fluid inside a micro-channel cold plate of the micro-channel heat exchanger system. At block 402, a first amount of heat is transferred from a first plurality of memory modules to a first micro-channel cold plate via a first TIM. A fluid flow is provided through a first plurality of micro-channels within the first micro-channel cold plate at block 404. At block 406, the first amount of heat is removed from the first micro-channel cold plate by the fluid flow through the first micro-channel cold plate. At block 408, a second amount of heat is transferred from a second plurality of memory modules to a second micro-channel cold plate via a second TIM. The fluid flow is provided through a second plurality of micro-channels within the second micro-channel cold plate at block 404. At block 406, the second amount of heat is removed from the second micro-channel cold plate by the fluid flow through the second micro-channel cold plate.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A device comprising:
a first thermal interface material in physical communication with a first plurality of memory modules of a computer system; and
a first micro-channel cold plate in physical communication with the first thermal interface material, the first micro-channel cold plate adapted to allow a fluid flow through a first plurality of micro-channels, and configured to remove a first amount of heat produced by the first memory modules of the computer system through the first thermal interface material.

2. The device of claim 1 wherein the first micro-channel cold plate is further configured to provide a substantially constant heat exchange amount across each of the first memory modules based on the fluid flow through the first plurality of micro-channels.

3. The device of claim 1 wherein the first thermal interface material is a thermally conductive material selected from a group consisting of a thin gap pad of filler material, a layer of grease, and a phase change material.

4. The device of claim 1 further comprising:
a second thermal interface material in physical communication with a second plurality of memory modules of the computer system; and
a second micro-channel cold plate in physical communication with the second thermal interface material, the second micro-channel cold plate adapted to allow the fluid flow through a second plurality of micro-channels, and configured to remove a second amount of heat produced by the second memory modules of the computer system through the second thermal interface material.

5. The device of claim 4 wherein the second micro-channel cold plate is further configured to provide a substantially constant heat exchange amount across each of the second memory modules based on the fluid flow through the second plurality of micro-channels.

6. The device of claim 4 wherein the second thermal interface material is a thermally conductive material selected from a group consisting of a thin gap pad of filler material, a layer of grease, and a phase change material.

7. The device of claim 4 wherein the fluid flow is substantially equal through both the first plurality of micro-channels and the second plurality of micro-channels.

8. A system comprising:
a hard disk drive;
a first thermal interface material in physical communication with the hard disk drive; and
a first micro-channel cold plate in physical communication with the first thermal interface material, the first micro-channel cold plate adapted to allow a fluid flow through a first plurality of micro-channels, and configured to remove a first amount of heat produced by the hard disk drive through the first thermal interface material.

9. The system of claim 8 wherein first micro-channel cold plate is further configured to provide a substantially constant heat exchange amount across the hard disk drive based on the fluid flow through the first plurality of micro-channels.

10. The system of claim 8 wherein the first thermal interface material is a thermally conductive material selected from a group consisting of a thin gap pad of filler material, a layer of grease, and a phase change material.

11. The system of claim 8 further comprising:
a plurality of memory modules;
a second thermal interface material in physical communication with the memory modules; and
a second micro-channel cold plate in physical communication with the second thermal interface material, the second micro-channel cold plate adapted to allow the fluid flow through a second plurality of micro-channels, and configured to remove a second amount of heat produced by the memory modules through the second thermal interface material.

12. The system of claim 11 wherein the second micro-channel cold plate is further configured to provide a substantially constant heat exchange amount across each of the memory modules based on the fluid flow through the second plurality of micro-channels.

13. The system of claim 11 wherein the second thermal interface material is a thermally conductive material selected from a group consisting of a thin gap pad of filler material, a layer of grease, and a phase change material.

14. The system of claim 11 wherein the fluid flow is substantially equal through both the first plurality of micro-channels and the second plurality of micro-channels.

15. A method comprising:
transferring a first amount of heat from a first plurality of memory modules to a first micro-channel cold plate via a first thermal interface material in physical communication with the first cold plate and with the first memory modules;
providing a fluid flow through a first plurality of micro-channels within the first micro-channel cold plate; and
removing the first amount of heat from the first micro-channel cold plate by the fluid flow through the first micro-channels.

16. The method of claim 15 further comprising:
transferring a second amount of heat from a second plurality of memory modules to a second micro-channel cold plate via a second thermal interface material having physical communication with the second cold plate and with the second memory modules;
providing the fluid flow through a second plurality of micro-channels within the second micro-channel cold plate; and
removing the second amount of heat from the second micro-channel cold plate by the fluid flow through the second micro-channels within the second cold plate.

17. The method of claim 16 wherein the fluid flow is substantially equal through both the first micro-channel cold plate and the second micro-channel cold plate.

18. The method of claim 16 wherein the first amount of heat and the second amount of heat are substantially equal.

19. The method of claim 16 further comprising:
increasing a thermal performance of the first and second micro-channel cold plates based on the fluid flow through each of the first and second micro-channels.

20. The method of claim 16 further comprising:
providing the fluid flow the first and second micro-channels at a low flow rate; and
providing a low thermal resistance between the first micro-channel cold plate and the fluid flow, and between the second micro-channel cold plate and the fluid flow.
